(19) United States
(12) Patent Application Publication
(10) Pub. No.: US 2012/0211064 A1
(43) Pub. Date: Aug. 23, 2012

(54) Semiconductor Layer Material and Heterojunction Solar Cell

(76) Inventors: Thomas Wagner, Leonberg (DE); Robert Roelver, Weil Der Stadt (DE)

(21) Appl. No.: 13/392,345

(22) PCT Filed: Jul. 7, 2010
(86) PCT No.: PCT/EP2010/059695

§ 371 Date: May 9, 2012

(30) Foreign Application Priority Data
Aug. 31, 2009 (DE) 10 2009 029 017.6

(51) Int. Cl. H01L 31/0352

(52) U.S. Cl. 136/255

(57) ABSTRACT

Semiconductor layer material, e.g., for use as an emitter material for a heterojunction solar cell, is formed as a stack made of multiple first layers and second layers alternatingly situated one on top of the other. The first layers is made of an elementary, polycrystalline semiconductor, and the second layer is made of a substoichiometric electrically insulating compound, e.g., an oxide, carbide, or nitride, of the semiconductor. The interfaces between the first layers and the second layers are irregularly structured by a temperature treatment in such a way that microcontact areas are formed between adjacent first layers, which are separated from one another by a second layer.

### BACKGROUND OF THE INVENTION

1. Field of the Invention

The present invention relates to a semiconductor layer material, e.g., for use as an emitter material for a solar cell, and a heterojunction solar cell.

2. Description of Related Art

Among the so-called renewable energy sources, solar energy is increasingly gaining in significance, because it has been possible to reduce the costs of the solar cell modules and the overall systems and to increase the energetic yield and therefore to bring the overall cost per unit of generated electrical power closer to the values which set the economic standard for power production based on fossil fuels. The photoelectric yield of the individual cells plays an important role.

Because of the low reverse saturation currents of the emitters in comparison to homojunction cells, significantly higher voltages may be achieved using heterojunction solar cells. The efficiency potential of heterojunction cells is 1-2% in absolute terms greater than the efficiency potential of homojunction cells. The heterojunction solar cells available up to this point have had a doped heteroemitter made of amorphous silicon (aSi); cf. M. Tanaka, M. Taguchi, T. Matsuyama, T. Sawada, S. Tsuda, S. Nakano, H. Hanafusa, Y. Kuwano, “Development of New a-Si/c-Si Heterojunction Solar Cells: ACJ-HIT (Artificially Constructed Junction-Heterojunction with Intrinsic Thin-Layer)” Jpn. J. Appl. Phys., 31, 3518-22 (1992) and T. Sawada, N. Terada, S. Tsuge, T. Baba, T. Akahama, K. Wakisaka, S. Tsuda, S. Nakano, “High efficiency a-Si/c-Si heterojunction solar cell.” Conference Record of the 1st WCPEC, Hawaii, 1994; 1219-1226.

The doping of the emitter allows the production of a pn-junction and therefore the extraction of the charge carriers generated by sunlight. The most important task of the amorphous silicon layer, which is typically between 5 nm and 20 nm thick, however, in this case is to passivate the wafer surface of the solar cell and thus decrease the recombination rate of the charge carriers generated by sunlight, whereby the concentration of the charge carriers in the solar cell increases. Due to the higher charge carrier concentration, greater splitting of the quasi-Fermi level occurs in the cell, which is equivalent to a higher achievable electrical voltage on the solar cell.

However, the high doping of the aSi emitter has the result that light absorbed in the emitter does not contribute to the power generation in the solar cell; cf. T. Mueller, S. Schwertheim, M. Scherff, W. R. Fahner, “High quality passivation for heterojunction solar cells by hydrogenated amorphous silicon suboxide films,” Appl. Phys. Lett., 92, 033504 (2008). The light absorbed in the emitter is lost to the energy conversion.

Passivation layers made of SiC or SiOₓ have already been tested as alternative materials to aSi in heterocells, cf. S. Miyajima, M. Sawamura, A. Yamada, M. Konagai, “Properties of n-type hydrogenated nanocrystalline cubil silicon carbide films deposited by VHF-PECVD at low substrate temperatures,” J. Noncryst. Solids, 354, 2350 (2008). The possibility has also already been studied of using materials including microcrystalline silicon, embedded in SiO₂, in heterojunction solar cells (SIPOS concept); cf. E. Yablonovich, T. Gmitter, R. M. Swanson, Y. H. Kwark, “A 720 mV open circuit voltage SiOx:c-Si:SiOx double heterostructure solar cell,” Appl. Phys. Lett., 47, 1211 (1985).

Materials of the last-mentioned type have a relatively low electrical conductivity, which restricts the possible applications. This problem is solved to a certain degree by a further relatively new material that includes alternating layers, which are each a few nanometers thick and include silicon and substoichiometric SiOₓ, cf. R. Rölver, B. Berghoff, D. Bätzner, B. Spangenberg, H. Kurz “Charge transport in Si/SiO2 multiple quantum wells for all silicon tandem solar cells”, Proceedings of the 22nd EU PVSEC, Milano (2007). Furthermore, so-called tandem solar cells based on silicon are known, in which stacks made of alternating silicon and SiOₓ layers are used as the light-absorbing and charge-carrier-generating layer of a solar cell.

### BRIEF SUMMARY OF THE INVENTION

The present invention is based on the object of providing an improved solution for the implementation of the emitter layer of a heterojunction solar cell, which in particular combines good passivation properties with sufficiently high conductivity and a high transparency to the active components of sunlight.

The most important advantage of the silicon-based nanostructured material proposed here as the heteroemitter is the essentially lower light absorption in comparison to the amorphous silicon used up to this point, whereby the losses by light absorption in the electrically “dead” amorphous silicon layer may be significantly minimized. The present invention provides, in other words, the advantage of reducing the losses due to photons absorbed in the emitter, which results in improved power yield in the solar cell and therefore a greater achievable efficiency, the material having comparable electrical properties (surface passivation and electrical conductivity).

An essential idea of the invention is to provide a novel silicon nanostructured material, which, because of its nanocrystalline structure, has a significantly higher optical transparency than the amorphous silicon used up to this point, but simultaneously displays similarly good passivation properties and similarly good electrical conductivity. Rough calculations have shown that efficiency improvements of up to 2% in absolute terms in comparison to heterocells having typical amorphous silicon emitters may be achieved using the proposed silicon nanostructured emitter because of its higher optical transparency.

This nanostructured material results in particular through alternating deposition of substoichiometric silicon oxide (SiOₓ)—(alternatively also silicon carbide (SiCₓ) or silicon nitride (SiNₓ))—layers and silicon layers in the layer thickness range of less than 10 nm. Through subsequent temperature treatment, especially around or above 1000° C., phase separation of the excess silicon occurs in the SiOₓ (alternatively SiCₓ, SiNₓ) and thus isotropic growth of the silicon layers occurs at the expense of the SiOₓ layers [6]. Contact points form between adjacent polycrystalline silicon layers, whereby an electrically conductive network made of silicon crystals results.

The proposed layer material is fundamentally also usable outside the use proposed here as an emitter material of a heterojunction solar cell. An embodiment which is particularly advantageous in the scope of the existing object provides that a delimitation layer of the stack is formed by a second layer and microcontact areas of the first layer adjacent thereto are exposed on its outer side.

The term “nanostructured material” used here means that at least the first layers have a nanocrystalline structure. In advantageous embodiments, it is provided that the thickness of the first layers and the second layers are each in the range between 1 nm and 20 nm, preferably between 2 nm and 10 nm. Furthermore, it is provided that in particular the total thickness is in the range between 5 nm and 100 nm, preferably between 10 nm and 60 nm. Furthermore, it is considered to be advantageous for the total number of the layers to be between 4 and 20, preferably between 8 and 16.

If a network of the mentioned type is doped, it may be used as an emitter in a solar cell. The semiconductor material—in particular silicon here—is doped in an advantageous embodiment as a p-material using phosphorus or as an n-material using boron having a concentration in the range between 10¹⁸ and 10²⁰ cm⁻³, in particular between 5×10¹⁸ and 5×10¹⁹ cm⁻³. Due to the property of this network of only forming a contact to the adjacent layer at individual points, transitions between the emitter layer and the silicon wafer only form more or less punctiformly when the heterojunction solar cell is used, while the majority of the wafer surface is passivated by SiO₂ (alternatively SiC or SiN). The advantage of good passivation of the wafer surface, which is also exploited in typical hetero solar cells, is thus maintained.

### BRIEF DESCRIPTION OF THE DRAWINGS

FIG. 1 shows a schematic view of the structure of a heterojunction solar cell, as a cross-sectional view.

FIGS. 2A and 2B show schematic cross-sectional views of a specific embodiment of the semiconductor layer material according to the present invention on a semiconductor substrate, after the deposition of a layer stack (FIG. 2A) and after a following temperature treatment (FIG. 2B).

FIG. 3 shows a comparative graph of the absorption spectra of amorphous silicon (solid line) and a semiconductor layer material according to the present invention (dashed line).

FIG. 4 shows a comparative graph of the electrical conductivities of various specific embodiments of the proposed semiconductor layer material as current-density-voltage characteristic curves.

### DETAILED DESCRIPTION OF THE INVENTION

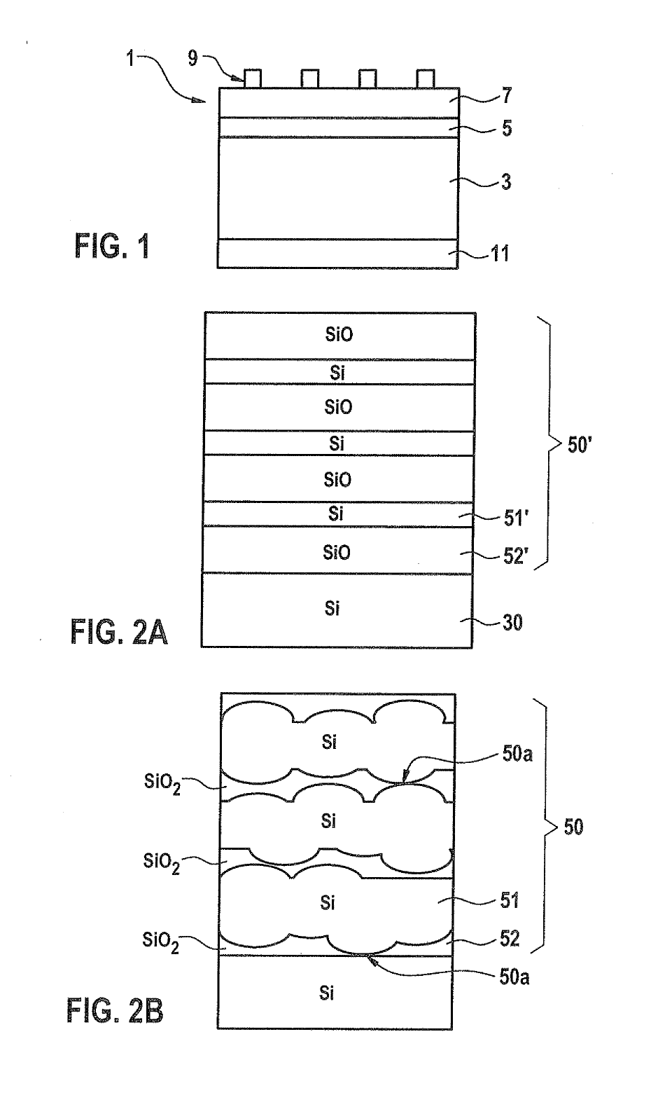

FIG. 1 shows a schematic cross-sectional view of the structure of a heterojunction solar cell 1 on a p-conductive or n-conductive silicon semiconductor substrate 3. A heteroemitter layer 5 is situated on silicon substrate 3 and a TCO layer 7 is situated on the heteroemitter layer. The layer structure is completed on the front side by a local front side contact 9, and on the rear side by a rear side contact 11 over the entire area.

FIGS. 2A and 2B show a stack 50′ or 50, respectively, made of a semiconductor layer material, which may be used as a heteroemitter layer 5 in the solar cell structure according to FIG. 1, on a silicon substrate 30. FIG. 2A shows the stack, which is identified by numeral 50′, after a first method step, and FIG. 2B shows the stack, which is then identified by numeral 50, after a second method step, and the reference numerals of individual layers of the stack (see below) are produced corresponding thereto.

As is clearly apparent from FIG. 2A, the layer stack is formed by successive silicon layers 51′, which are particularly deposited one on top of the other, as “first layers” and SiO layers 52′ as second layers. It is apparent that the layer of the stack immediately adjacent to silicon substrate 30 is an SiO layer 52′, i.e., a layer here also referred to as a “second layer.” The cover layer of the stack is also formed by such a second layer 52′. Silicon layers 51′ are doped, and SiO layers 52′ are substoichiometric layers, and the layer thicknesses are each less than 10 nm.

FIG. 2B shows structure 50, which arose as a result of a subsequent temperature treatment at temperatures >1000° C., in which the interfaces between the first layers and the second layers are irregularly structured in such a way that microcontact areas (“point contacts”) 50a are formed in each case between adjacent first layers 51, which are separated from one another by a second layer 52, and at the interface to silicon substrate 30. The configuration of this structure having the microcontact areas, which are essential for the function of the layer structure according to the present invention, is linked to the unmixing of silicon and stoichiometric SiO₂ during the temperature treatment, in the scope of which the silicon saturated layers grow isotropically. Contacting of the free surface of the layer stack used as the heteroemitter layer in a solar cell of the type shown in FIG. 1 only occurs after the temperature treatment.

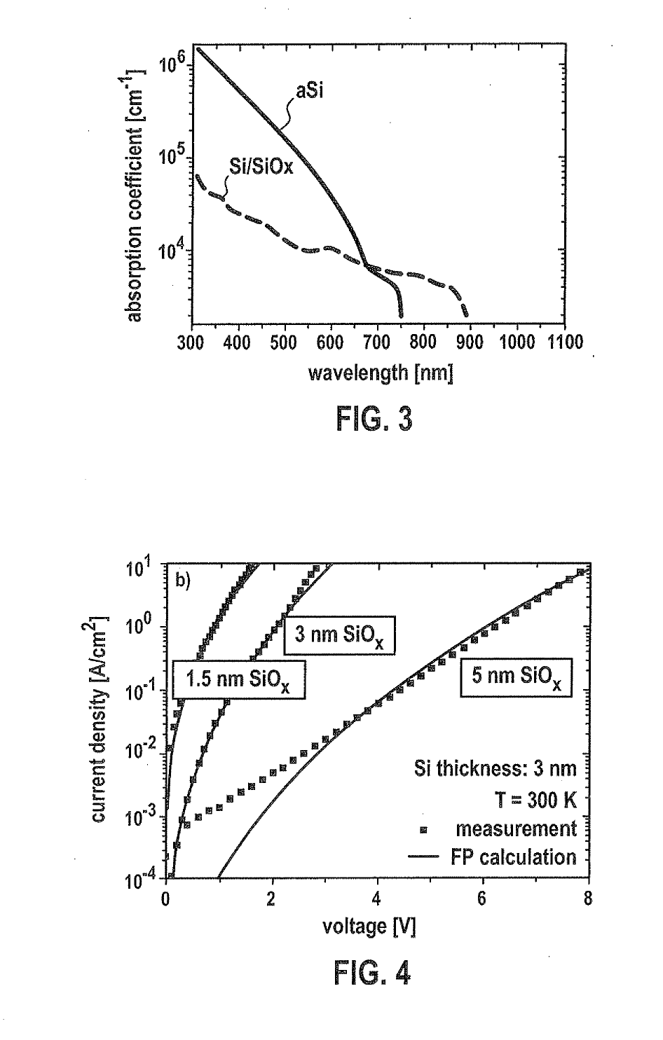

FIG. 3 shows that the absorption coefficient of semiconductor layer material constructed according to the present invention as the emitter material (dashed curve) in the range below approximately 680 nm, i.e., in the range of visible light, is advantageously lower than that of a comparable layer made of amorphous silicon (solid line).

Finally, FIG. 4 shows current-density-voltage characteristic curves of differently structured semiconductor layer stacks made of silicon and SiOₓ having a total thickness of 60 nm each and matching thicknesses of the first layers (3 nm) and different thicknesses of the second layers (1.5-5 nm) before the temperature treatment. It is apparent that the respective measured values are a good match with the respective calculated curves (with the exception of voltages less than 3 V for the embodiment having 5-nm thick SiOₓ layers). It is also apparent in particular that it is possible by selecting the thicknesses of the second layers to set the electrical conductivity of the proposed semiconductor layer material in a wide range.

The embodiment of the present invention is not restricted to the above-explained examples and emphasized aspects, but rather is also possible in manifold alterations, which are within the scope of typical measures in the art.

1-10. (canceled)

11. A semiconductor layer material configured as an emitter material for a heterojunction solar cell, comprising:
multiple first layers and multiple second layers provided in a stack, wherein first layers and second layers are alternatingly situated one on top of the other;
wherein the first layers include an elementary, polycrystalline semiconductor and the second layers include a substoichiometric electrically insulating compound including one of an oxide, carbide, or nitride of the semiconductor, and wherein interfaces between the first layers and the second layers are irregularly structured by a temperature treatment in such a way that microcontact areas are formed between adjacent first layers which are separated from one another by a second layer.

12. The semiconductor layer material as recited in claim 11, wherein a delimitation layer of the stack is formed by a second layer, and wherein microcontact areas of the first layer adjacent to the delimitation layer are exposed on the outer side of the delimitation layer.

13. The semiconductor layer material as recited in claim 12, wherein the semiconductor is silicon.

14. The semiconductor layer material as recited in claim 12, wherein the semiconductor is doped as one of (i) a p-material using phosphorus or (ii) an n-material using boron, having a doping concentration in the range of 10¹⁸ to 10²⁰ cm⁻³.

15. The semiconductor layer material as recited in claim 12, wherein at least the first layers have a nanocrystalline structure.

16. The semiconductor layer material as recited in claim 12, wherein the thickness of the first layers and the second layers is in the range of 1 nm to 20 nm.

17. The semiconductor layer material as recited in claim 12, wherein the total thickness of the stack is in the range of 5 nm to 100 nm.

18. The semiconductor layer material as recited in claim 12, wherein the total number of the first and second layers in the stack is between 4 and 20.

19. A heterojunction solar cell, comprising:
a semiconductor substrate; and
a doped heteroemitter layer situated on the semiconductor substrate;
wherein the doped heteroemitter layer (i) forms an outer surface of the solar cell, and (ii) acts as a passivation layer;
wherein the doped heteroemitter layer is formed by a semiconductor layer material having multiple first layers and multiple second layers provided in a stack, wherein first layers and second layers are alternatingly situated one on top of the other, wherein the first layers include an elementary, polycrystalline semiconductor and the second layers include a substoichiometric electrically insulating compound including one of an oxide, carbide, or nitride of the semiconductor, and wherein interfaces between the first layers and the second layers are irregularly structured by a temperature treatment in such a way that microcontact areas are formed between adjacent first layers which are separated from one another by a second layer;
wherein a delimitation layer of the stack is formed by a second layer, and wherein microcontact areas of the first layer adjacent to the delimitation layer are exposed on the outer side of the delimitation layer; and
wherein the outer side of the semiconductor layer material, on which the microcontact areas of the first layer are exposed, is adjacent to the semiconductor substrate.

20. The heterojunction solar cell as recited in claim 19, wherein the semiconductor substrate is a silicon wafer.
